(19) United States
(12) Patent Application Publication
(10) Pub. No.: US 2002/0118507 A1
(43) Pub. Date: Aug. 29, 2002

(54) Multiple form factor PC card system

(75) Inventors: Vladimir Paredes, San Jose, CA (US); Karch Polgar, San Jose, CA (US); Mark S. Smith, San Jose, CA (US)

Correspondence Address: ERIC L. MASCHOFF, WORKMAN NYDEGGER & SEELEY, 1000 EAGLE GATE TOWER, 60 EAST SOUTH TEMPLE, SALT LAKE CITY, UT, 84111, US

(73) Assignee: 3Com Corporation

(21) Appl. No.: 09/795,169

(22) Filed: Feb. 28, 2001

(51) Int. Cl. G06F 1/16; H05K 5/00

(52) U.S. Cl. 361/684; 361/728; 361/730; 361/737

(57) ABSTRACT

A PC card communication system for facilitating both wireless and hardwire based communication between a host device, in which the PC card communication system is received, and one or more remote devices. The PC card communication system includes a wireless PC card conforming to a Type II form factor and containing two antennae, one each of which is disposed on opposing sides of a recess defined by a housing of the wireless PC card. The PC card communication system additionally includes a combination PC card conforming to a Type III factor, and which includes RJ-11 and RJ-45 connectors having a connector body centered in a front edge of a housing of the combination PC card. The recess defined by the wireless PC card, and the connector body of the combination PC card, are configured and arranged so that at least a portion of the connector body may be received in the recess. As a result of this arrangement, the wireless PC card and the combination PC card collectively conform to a Type III form when the connector body is so received and, accordingly, can be employed contemporaneously in a single Type III PC card slot of a host computer. This arrangement also permits removal of the combination PC card from the PC card slot without also necessitating the removal of the wireless PC card. Finally, such an arrangement contributes to a desirable separation of the antennae of the wireless PC card.

### BACKGROUND OF THE INVENTION

1. The Field of the Invention

The present invention relates generally to PC Cards, and related modular peripheral devices for use in a host electrical device. More particularly, embodiments of the present invention relate to improved PC cards having novel form factors that allow for concurrent use within a compatible slot in a host electrical device.

2. Related Applications

Advances in the power and sophistication of computer application software, operating systems, communications software, and peripheral devices have required the development of computers with greater processing speeds and capacities. At the same time however, the pressure to at least maintain, and preferably reduce, the physical size of the computer and its various components has increased as well. Accordingly, downsizing and miniaturization of computer components is an issue of great importance in the industry.

To that end, manufacturers have developed an increasing number of miniature portable expansion devices to add functionality to host devices. One example of these expansion devices are known as “PC cards.” Examples of such PC cards include cards that increase the memory storage of a host; cards that provide for “wired” communications, such as modem cards and network interface cards; and cards that provide for wireless communication. The typical PC card was designed to plug into a port, slot, or socket in the host device. As a result, PC cards serve to expand the power and functional capability of the host device without significantly increasing the size of the physical envelope of the host.

Increasingly, such expansion devices are built in accordance with prescribed physical and electrical standards, so as to insure compatibility from one manufacture to another. For example, a number of manufacturers collaborated to form the Personal Computer Memory Card International Association (PCMCIA), which specifies standards for the physical design, dimensions, and electrical interface of PC cards. For example, PCMCIA standards provide for, among other things, Type I, Type II, and Type III form factors (hereinafter the “Type I,” Type II,” and “Type III ” standards, as applicable) wherein each form factor is characterized by specific dimensional attributes. Generally, the length and width characteristics of all PC cards conforming to PCMCIA standards are the same. More specifically, all PC cards conforming to such standards are 85.6 millimeters long and 54 millimeters wide. The distinguishing physical characteristic among the various PCMCIA form factors is the thickness of a particular PC card. In particular, Type I cards are 3.3 millimeters thick Type II cards are 5.0 millimeters thick, and Type III cards are 10.5 millimeters thick.

PCMCIA standards also define the electrical interface requirements for both the card and the host device. A host device will typically include one or more PC card slots, having PCMCIA-defined electrical and physical interfaces. For example, a common configuration provides a PCMCIA slot, which may have two adjacent 68-pin connectors for physically and electrically interfacing with two PC cards. In this configuration, two PCMCIA PC cards conforming with the Type II standard can be simultaneously received within the two adjacent 68-pin connector slots. Alternatively, a single Type III PC card can be received within one of the 68-pin connector slots.

In the PCMCIA slot configuration of many host devices, PC cards having dissimilar form factors, such as a Type II card and a Type III card, cannot simultaneously reside in adjacent PCMCIA 68-pin connector slots, due to the proximity of the 68-pin connectors and the height profile of the Type III card. This can limit a user's ability to utilize multiple PC cards. For example, a “combo” PC card that provides “wired” communications—such as modem and LAN communications—may have integrated RJ-modular receptacles (e.g., RJ-11, RJ-45) that present a card height similar to a Type III thickness. Until now, the presence of such a card could preclude the simultaneous use of another Type II card, such as one that provides for wireless communications, in an adjacent 68-pin connector slot. In this situation, the user must first physically remove the Type III card, and then insert the Type II card. Obviously, this is inconvenient, time consuming, and limits the functionality available to the host device at any given time.

The ability to utilize adjacent expansion cards is further limited when one of the cards requires a particular physical configuration—such as a PC card providing wireless communication functions. For example, if a card is residing in an adjacent slot, its presence may limit the ability to provide optimal antenna separation in a wireless PC card. In general, wireless PC card performance increases with antennae separation, so as to reduce so-called “dead spots” of a wireless signal. Accordingly, where the antennae are disposed relatively close to each other, the effectiveness of the wireless PC card can be impaired. Furthermore, optimally the antennae should protrude from the front face of the host computer in order to be most effective. Both objectives are difficult to achieve, especially when another PC card is positioned within an adjacent slot.

In view of the foregoing problems and shortcomings, and others, with existing PC cards, it would be an advancement in the art to provide a system comprised of PC cards that collectively have geometries that allow the cards to be used contemporaneously within adjacent slots. Further, embodiments of the improved PC card system should allow such contemporaneous use even where one of the PC cards has a form factor that would otherwise preclude the presence of an adjacent card. Also, embodiments of the improved PC card system should provide form factors that are suitable for use with PC cards that provide for wireless communications. In particular, it would be an advancement in the art to provide a multiple form factor PC card communication system for simultaneously implementing both wireless and hardwire communication capabilities in a single PC card slot, having adjacent 68-pin connectors, of a host device.

### SUMMARY OF PRESENTLY PREFERRED EMBODIMENTS OF THE INVENTION

The present invention has been developed in response to the current state of the art, and in particular, in response to problems and needs that have not been fully or adequately resolved by currently available existing PC card systems. Embodiments of the present invention provide PC a system of cards that together are capable of defining a collective form factor that permits the cards to reside within adjacent electrical connector slots of a host electronic device. The ability to utilize multiple adjacent cards provides additional operational flexibility for the host device.

Presently preferred embodiments are particularly well suited for use in 32-bit CardBus-compliant host computers and applications where it is desired to achieve, in adjacent PC card slots of a host computer, both wireless and hardwire based communication capabilities implemented by way of PCMCIA-compliant PC cards. However, it will be appreciated that embodiments of the present invention may be suitable for use in conjunction with a variety of different types of electrical host devices, as well as with various other PC card-type expansion devices conforming to any of a number of other standards, form factors, or geometric configurations providing other communication or expansion functions.

In one embodiment of the present invention, a PC card system is provided that includes a first PC card having a housing which substantially complies with the PCMCIA Type II length and width standards, and that further includes at least one integrated RJ-type connector receptacle. For example, the first card may include one RJ-11 connector and one RJ-45 connector, for facilitating hardwire based communication between a host device and one or more remote devices. Preferably, the connectors include a common receptacle body that is integral with the housing and that is positioned substantially at the center of a front edge of the PC card housing. As is well known, this receptacle body presents a height that exceeds the thickness specified by the Type II standard, and more closely approximates the thickness specified by the Type III standard. The first PC card of a preferred embodiment includes modem circuitry and network interface circuitry connected, respectively, to the RJ-11 and RJ-45 connectors. The first PC card further includes a PCMCIA standard 68-pin connector joined to the modem and network interface circuitry, which provides the means for physically and electrically connecting to a corresponding 68-pin connector disposed in the PC card slot of the host device.

Many host devices provide a “port” or slot having two 68-pin electrical connectors disposed therein. Each 68-pin electrical connector has a corresponding slot mechanism for operatively receiving a Type II PC card. Thus, two Type II cards are able to simultaneously reside and operate within the two adjacent connector slots. Ordinarily, the “full height” modular connector receptacle in the first card would preclude the card's simultaneous use in the host slot if another PC card resides in an adjacent 68-pin connector. In particular, the excessive height of the connector would block access to an adjacent PCMCIA 68-pin connector, in those hosts that are equipped with a PCMCIA slot configuration designed to receive two adjacent cards having a Type II form factor. However, the PC card communications system of the present invention includes a second PC card having a housing conforming to the Type II standard, and that defines a geometry that is complementary to that of the first card in a manner that allows it to be used simultaneously with the first card—notwithstanding the presence of the modular receptacle connector.

In a preferred embodiment, this complimentary shape is provided in housing of the second card, which defines a recessed portion. For example, the recess is defined and formed by first and second extending portions formed in the housing, and with a size and shape that substantially corresponds to the width of the RJ-type connector receptacle body of the first PC card.

In operation, the second PC card is inserted in the PC card slot of the host computer so that a 68-pin connector of the second PC card is releasably engaged by one of the 68-pin connectors of the PC card slot. Upon insertion of the second PC card, the first PC card may then likewise be inserted in the PC card slot, and received within the adjacent 68-pin connector. As the first PC card is inserted into the PC card slot, the uniquely shaped and positioned connector body of the card is received in and accommodated by the corresponding recess defined by the housing of the second PC card. Thus, both PC cards card can be fully received in the PC card slot and interfaced via adjacent 68-pin connectors, notwithstanding the presence of the full height connector receptacles on the first card. Preferably, the first and second cards collectively define an outer perimeter having a height or thickness that conforms substantially to the Type III standard. In this way, a Type II card and a PC card having at least a partial height corresponding to the Type III standard may be contemporaneously and operatively received in a single Type III PC card slot.

Furthermore, the arrangement of the connector body of the first PC card with respect to the recess defined by the second PC card permits the combination PC card to be subsequently withdrawn from the PC card slot without also requiring the removal of the second PC card. Thus, the function provided by the second PC card can be maintained even when the first PC card is removed and/or replaced.

In one presently preferred embodiment, the second PC card provides a wireless communication function. In this embodiment, the housing serves not only to define a recess, but does so in a manner that provides for an improved wireless communication. To do so, a first and a second antenna are disposed in the first and second extending portions respectively. Thus, the recess formed between the extending portions serves to maximize the distance between the respective antenna and thereby improves the performance of the wireless PC card. Preferably, the housing is comprised of a rugged material such as plastic or the like, which serves to minimize the weight of the wireless PC card while at the same time providing a rugged and durable housing for the antenna.

Thus, embodiments of the present invention include a variety of useful features. In particular, the unique form factor provided by the PC cards allows two cards to operatively reside in adjacent connector slots, notwithstanding the presence of a full height modular connector, or the like, on one of the cards. Moreover, the novel housing design also serves to improve the quality of wireless communication provided by a wireless PC card, and also does so in a manner that provides improved protection to the card's antennae.

These and other objects, features and advantages of the present invention will become more fully apparent from the following description and appended claims, or may be learned by the practice of the invention as set forth hereinafter.

### BRIEF DESCRIPTION OF THE DRAWINGS

In order that the manner in which the above-recited and other advantages and features of the invention are obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1 illustrates an exemplary operating environment for embodiments of the present invention;

FIG. 2 is an exploded front perspective view depicting various details of a wireless PC card and combination PC card in an embodiment of a PC card communication system consistent with the teachings of the present invention;

FIG. 3 is a front perspective view illustrating various details regarding the arrangement of a PC card communication system consistent with the teachings of the present invention;

FIG. 4 is an exploded rear perspective view depicting various details of a wireless PC card and combination PC card in an embodiment of a PC card communication system consistent with the teachings of the present invention;

FIG. 5 is a rear perspective view illustrating various details regarding the connection and arrangement of a PC card communication system consistent with the teachings of the present invention; and

FIG. 6 is a front view illustrating the arrangement of a wireless PC card and combination PC card in an embodiment of a PC card communication system according to the present invention.

### DETAILED DESCRIPTION OF THE PREFERRED EMBODIMENTS

Reference will now be made to figures wherein like structures will be provided with like reference designations. It is to be understood that the drawings are diagrammatic and schematic representations of various embodiments of the claimed invention, and are not to be construed as limiting the present claimed invention, nor are the drawings necessarily drawn to scale.

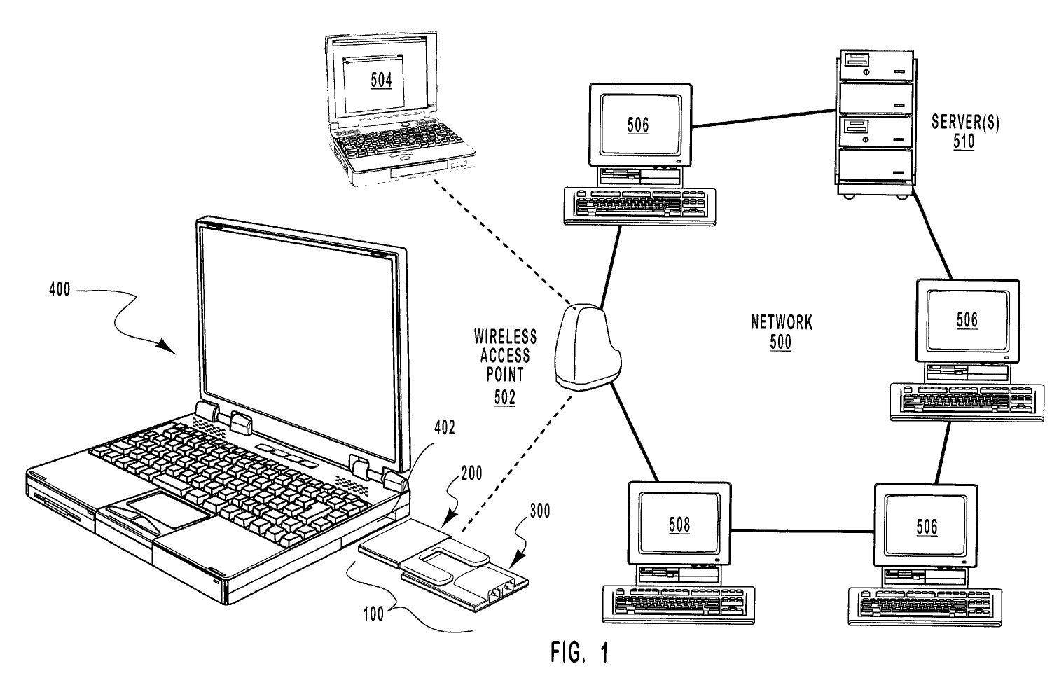

Reference is first made to FIG. 1, wherein a PC card communication system is indicated generally at 100. In the illustrated embodiment, the PC card communication system includes a wireless PC card 200 for facilitating wireless communication between a host device and any of a variety of other systems and remote devices, and a combination PC card 300. Note that various embodiments of wireless PC card 200 and combination PC card 300 are disclosed and claimed in the Wireless Card & Combination Card Applications incorporated by reference herein. It will be appreciated that while the embodiment disclosed portrays the system as using specific types of PC cards providing a wireless and a “wire” communication function, that the invention should not be limited to those types of cards. To the contrary, the present invention would be applicable to cards providing any one of a number of different functions, and/or that utilize any one of a number of sizes and form factors, including those not yet developed.

In general, “combination” PC card 300 generally refers to PC cards which incorporate a plurality of functionalities. One example of such a combination PC card is one which includes both an RJ-11 and RJ-45 connector, each of which has associated therewith a particular functionality. In this example, the RJ-11 connector permits a host device, by way of the combination PC card, to communicate with remote devices via the public telephone network, and the RJ-45 connector of the combination PC card permits the host device to communicate with networks such as Local Area Networks (LAN) such as Ethernet and others. Thus, the exemplary combination PC card possesses at least two different functionalities. Again, it will be appreciated that combination PC card 300 may incorporate a variety of additional or alternative functionalities as well.

In general, both wireless PC card 200 and combination PC card 300 are configured to physically and electrically interface with a host computer 400 having one or more PC card slots 402. It will be appreciated that host computer 400 may conform to any of a variety of configurations including, but not limited to, a laptop computer or other type of portable computer, a standard desktop personal computer, a handheld PDA, or any other appropriately configured electronic host device.

As in the case of host computer 400, wireless PC card 200 and combination PC card 300 may assume any of a variety of different configurations. For example, wireless PC card 200 comports with the PCMCIA Type II standard, and combination PC card 300, while having a length and width consistent with the Type II standard, includes one or more full height connectors, discussed below, having a height consistent with the Type III standard. In the illustrated example, PC card slot 402 is capable of receiving a single card conforming to the Type III standard, or two cards conforming to the Type II standard. As is discussed in further detail below, the present system allows a Type II card and a card having Type III characteristics to simultaneously reside in the slot.

While at least some embodiments of the present invention preferably conform to PCMCIA standard form factors and the like, the scope of the present invention should not be construed to be limited solely to combination PC cards conforming to PCMCIA form factors, electrical parameters, and operational parameters. Rather, it will be appreciated that PC card communication system 100, wireless PC card 200 and/or combination PC card 300 may be configured to individually and/or collectively conform to various other physical and electrical standards, form factors, and the like, as required to suit a particular application or computer hardware, and/or to facilitate achievement of one or more desired results.

In one embodiment of the present invention, PC card communication system 100 facilitates, among other things, the wireless and/or hardwire connection of host computer 400 to network 500, and thus, the transmission of communications therebetween. As contemplated herein, a “hardwired” device or “hardwire” connection refers to arrangements, connections, and/or devices wherein a physical electrical connection between computers and other devices is implemented which facilitate communication therebetween. On the other hand, a “wireless” device or “wireless” connection refers to arrangements, connections, and/or other devices wherein computers and devices are able to communicate with each other by way of radio signals or the like and, accordingly, do not require a physical connection with each other. Note that additional details regarding exemplary connections between host computer 400, and network 500 and/or various remote devices, are provided in the context of the Wireless Card & Combination Card Applications.

With continuing reference to FIG. 1, it will be appreciated that network 500 may comprise various types of hardwired and wireless remote devices, consistent with variables including, but not limited to, installation constraints, operational requirements of the network, cost considerations, and the like. In the exemplary embodiment illustrated in FIG. 1, network 500 includes, among other things, a wireless access point 502 configured, in various embodiments, for hardwire and/or wireless communication with host computer 400 and both wireless and hardwired remote devices. As discussed in further detail below, wireless access point 502 serves to facilitate communication between host computer 400 and one or more remote devices.

Additionally, network 500 preferably includes one or more remote computers 504 configured for wireless communication with wireless access point 502, as well as one or more remote computers 506 and 508 either directly connected to host computer 400, or configured and arranged for hardwire communication with host computer 400 by way of one or more intermediate remote computers. It will be appreciated that network 500 may additionally include one or more hardwired servers 510 in communication with remote computers 504, 506, and 508, as well as one or more wireless servers (not shown) configured for wireless communication with wireless access point 502 and/or remote computer 504.

Note that, as suggested above, “remote device” refers to any device or system configured for communication with host computer 400, either indirectly, such as in the case of remote computers 504 and 506, or directly, such as in the case of wireless access point 502 and remote computer 508. Furthermore, “remote device” not only comprehends the device, or devices, such as remote computers 504, 506, and 508, which is/are the ultimate destination, or origination point, of communications, but may additionally or alternatively comprise intermediate devices, such as wireless access point 502 which, while they transmit/receive communications to/from host computer 400 and/or one or more remote devices, may not be the ultimate destination for such communications.

Finally, while embodiments of the present invention may be usefully employed in the context of operating environments such as network 500, it will be appreciated that other operating environments for embodiments of the present invention are likewise appropriate. Thus, embodiments of the present invention may be used to facilitate or implement, among other things, hardwire and/or wireless communication between host computer 400 and, for example, cellular, satellite, or hardwired telephones, so-called “personal data assistants” (PDA), wireless access point 502, and a variety of other systems and devices.

Directing continuing attention to FIG. 1, various details are provided regarding various operational features of an embodiment of PC card communication system 100. In the case of the illustrated embodiment, a communication initiated at host computer 400 may be passed to one or more remote devices of network 500 either by way of wireless PC card 200, or by way of combination PC card 300, and, or alternatively, a communication is initiated at one or more remote devices and transmitted to host computer 400 by way of wireless PC card 200 and/or combination PC card 300. Thus, wireless PC card 200 and combination PC card 300 act as interfaces which facilitate communication between host computer 400 and one or more remote devices. In one embodiment, discussed in detail below, combination PC card 300 includes analog modem circuitry and network circuitry interface that serve to facilitate implementation of hardwire based communication between combination PC card 300 and remote devices and networks. Note that, as contemplated herein, materials transmitted by way of such “communications” include, but are not limited to, data, electronic mail, instructions, programs, files, electronic media, and any other material embodied in a form capable of being transmitted from or to host computer 400 by way of wireless PC card 200 and/or combination PC card 300.

While the embodiment illustrated in FIG. 1 indicates a host computer 400 configured for, among other things, both wireless and hardwire communication with network 500, it will be appreciated that host computer 400 is not limited solely to communicating with a single network 500. Preferably, wireless PC card 200 facilitates communication between host computer 400 and one network, and combination PC card 300 facilitates communication between host computer 400 and another network. That is, embodiments of PC card communication system 100 implement, among other things, the capability of simultaneous communication with a plurality of networks, from a single host computer 400.

As suggested above, communications initiated at host computer 400 may be transmitted to any of a variety of remote devices. In the context of network 500, for example, a communication initiated at host computer 400 may be transmitted to wireless access point 502 either by way of wireless PC card 200, or by way of combination PC card 300 if host computer 400 is hardwired to wireless access point 502, and then relayed by wireless access point 502 to one or more hardwired devices, such as remote computers 506 and 508, connected to wireless access point 502, and/or to one or more wireless remote devices such as remote computer 504. It will be appreciated that communication between host computer 400 and one or more remote devices, by way of wireless PC card 200 and/or combination PC card 300, may be performed in response to input provided to host computer 400 by a user, and/or may be performed automatically according to various criteria embodied in hardware and/or software associated with host computer 400. Likewise, it will be appreciated that communication with host computer 400 may be initiated by, or at, one or more remote devices, including, but not limited to, remote computers 504, 506 and 508, and wireless access point 502.

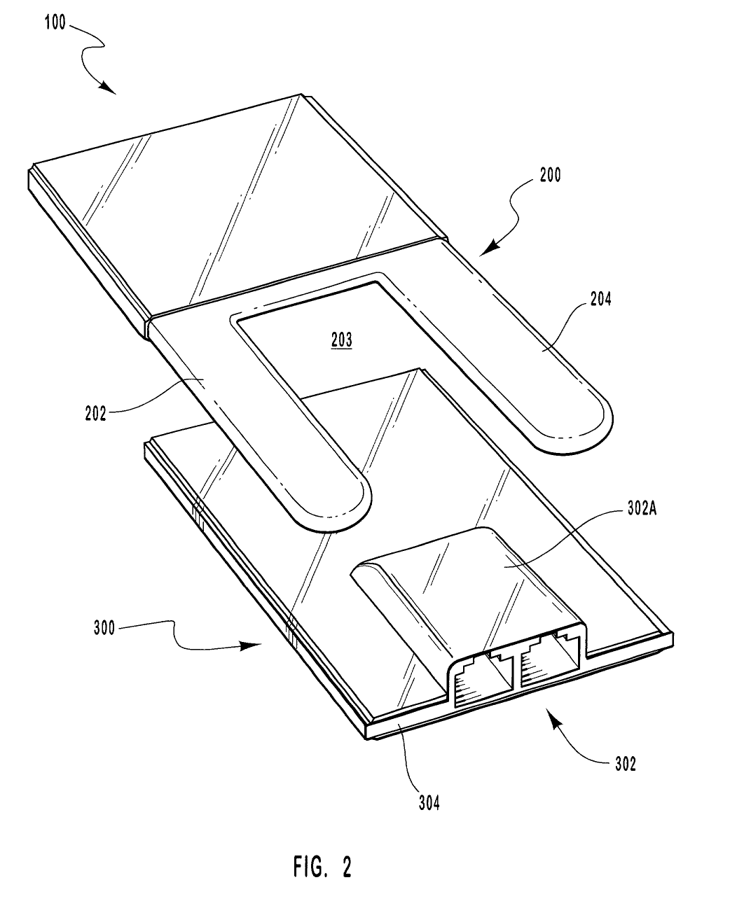

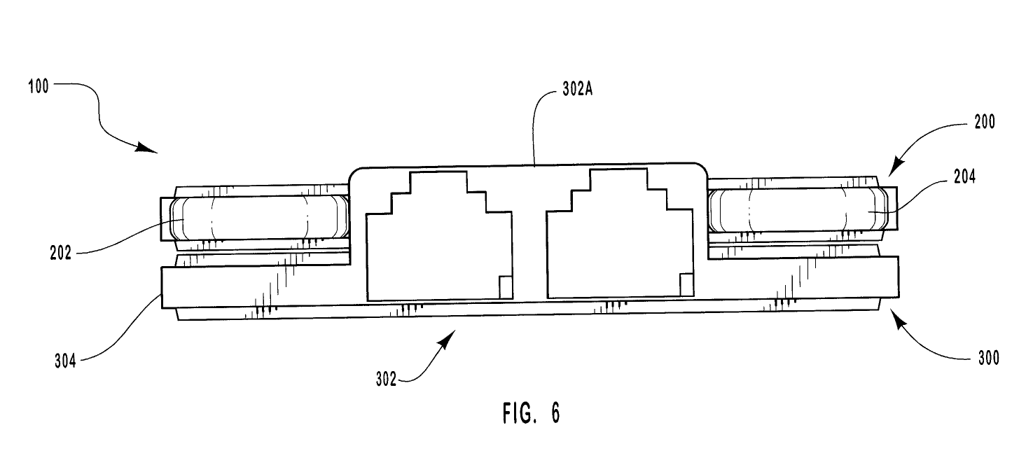

As details regarding various specific features and components of embodiments of wireless PC card 200 and combination PC card 300 are disclosed and claimed in the Wireless Card & Combination Card Applications, the following discussion of FIGS. 2 through 6 will be directed primarily towards the relationship between wireless PC card 200 and combination PC card 300 in the context of PC card communication system 100. Note however, that FIGS. 2 through 6 simply depict one exemplary embodiment of the present invention and that wireless PC card 200 and/or combination PC card 300 may be otherwise configured or arranged, with respect to each other and/or host computer 400, as required to implement one or more particular desired functionalities and/or to achieve one or more desired results.

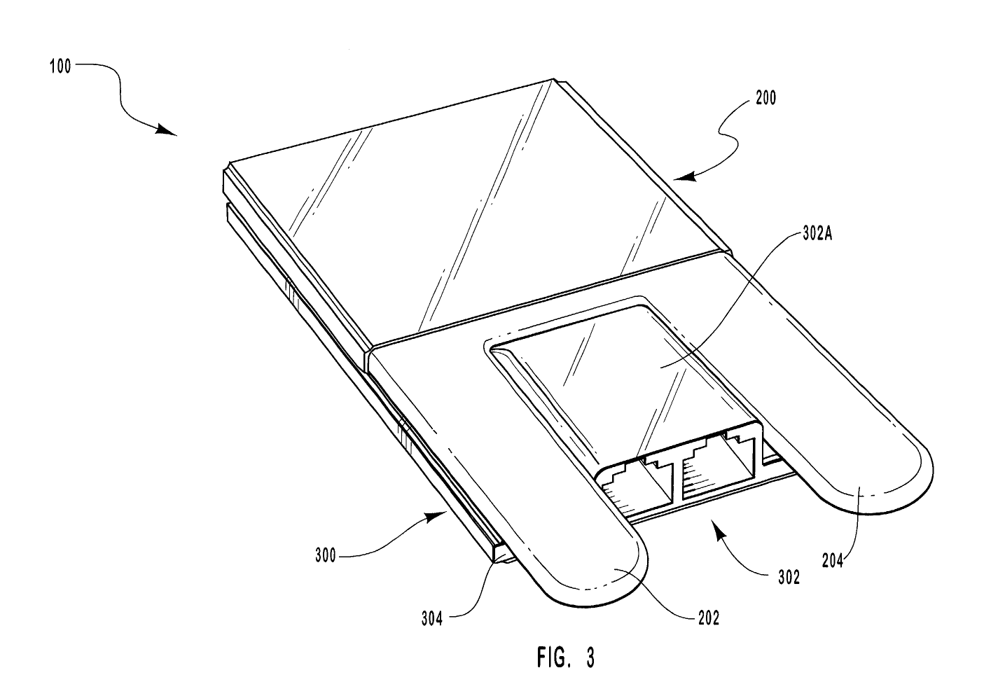

Directing attention now to FIGS. 2 and 3, additional details are provided regarding various features of an embodiment of PC card communication system 100. As noted above, wireless PC card 200 preferably conforms to the Type II standard and combination PC card 300, while having a length and width consistent with Type II standards, includes a plurality of connectors 302, preferably of the RJ-type, having a connector body 302A which conforms substantially with the Type III height standard. Thus, when placed together in the arrangement indicated in FIG. 3, the system formed by wireless PC card 200 and combination PC card 300 collectively conform with the Type III standard and, accordingly, are suited for contemporaneous use in the context of a single PC card slot (such as shown in FIG. 1) conforming to the Type III standard.

Accordingly, embodiments of the present invention are effective to implement, among other things, the contemporaneous use, of a wireless PC card and a combination PC card, wherein the wireless PC card conforms to one form factor and the combination PC card conforms to another, different, form factor. Further, at least one embodiment of the present invention implements the contemporaneous use, of a Type II wireless PC card and a combination PC card employing one or more full height, or Type III, height connectors.

As best illustrated in FIGS. 2, 3, and 6, this result is achieved in an exemplary embodiment by way of complementary geometric features of wireless PC card 200 and combination PC card 300, respectively. In particular, connector body 302A, situated at the center of front edge 304 of combination PC card 300, is configured to be at least partially received within a recess portion formed within the PC card 200. For example, in the illustrated embodiment, a recessed portion 203 is between a first extending portion 202 and second extending portion 204 of wireless PC card 200.

The positioning of connector body 302A at the center of front edge 304 of combination PC card 300 facilitates, and is consistent with, the antenna separation that is required for optimal operation and reliability of wireless PC card 200. In particular, the geometry of combination PC card 300 permits the antennae (not shown) of wireless PC card 200 to desirably reside in a spaced arrangement, specifically, an arrangement wherein one antenna is disposed in first extending portion 202 and another in second extending portion 204.

Another useful capability afforded by the aforementioned exemplary configuration and arrangement relates to the recess 203 defined by first extending portion 202 and second extending portion 204 of wireless PC card 200. In particular, the configuration and placement of such recess not only permits the contemporaneous use of the card 300 and its full height connectors 302 thereby enhancing the operational flexibility and capability of the host computer, but does so in a way that is sensitive to, and consistent with, the operational requirements and objectives of wireless PC card 200.

Yet another example of a useful feature implemented by embodiments of the present invention concerns the interaction between wireless PC card 200 and combination PC card 300 when, for example, it is desired to remove combination PC card 300 from PC card slot 402 (not shown) and replace combination PC card 300. As noted above, connector body 302A of combination PC card 300 is configured and arranged to be removably received within a recess 203 defined by wireless PC card 200. Further, neither wireless PC card 200 nor combination PC card 300 relies on the other for their respective functionality. Consequently, combination PC card 300 can be readily removed and replaced without also necessitating the removal of wireless PC card 200 from PC card slot 402. This feature serves to enhance the operational flexibility of host computer 400 by permitting removal and/or replacement of combination PC card 300 without compromising the integrity of the wireless connection implemented by way of wireless PC card 200, and by permitting replacement of combination PC card 300 with another PC card having capabilities consistent with a particular desired objective.

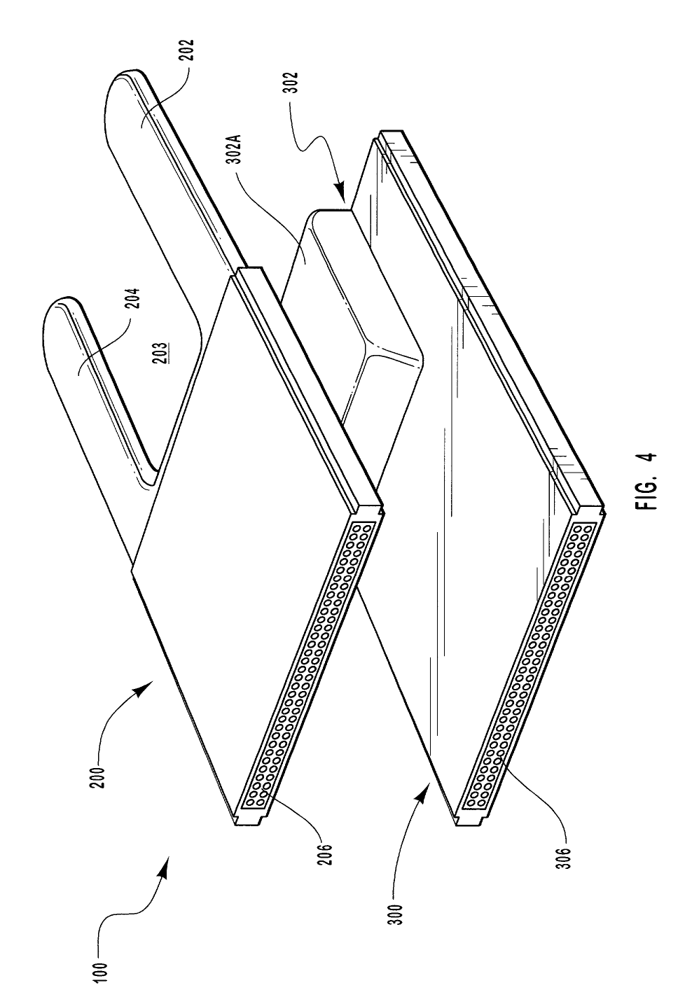

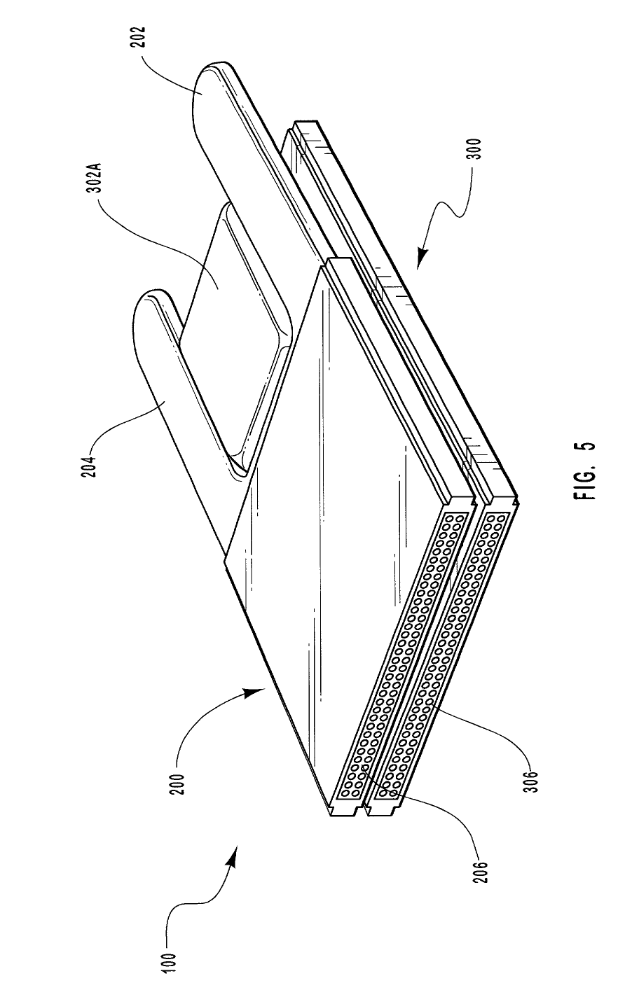

Directing attention now to FIGS. 4 and 5, details are provided regarding various additional features and aspects of an embodiment of PC card communication system 100. Specifically, wireless PC card 200 and combination PC card 300 each include connectors, 206 and 306, respectively, which allow those respective PC cards to physically and electrically interface with host computer 400. In the illustrated embodiment, connectors 206 and 306 each comprise a PCMCIA standard 68-socket connector. As suggested in FIG. 5, when wireless PC card 200 and combination PC card 300 are arranged for contemporaneous use in PC card slot 402, connectors 206 and 306 are arranged and aligned to physically and electrically interface with, respectively, adjacent 68-pin connectors disposed within PC card slot 402.

It will be appreciated that connectors 206 and 306 may take any of a variety of other forms as may be required for consistency and compatibility with the configuration of host computer 400, PC card slot 402, other hardware, and/or applicable electrical power constraints. Accordingly, the scope of the present invention should not be construed to be limited solely to standard 68-socket connectors.

Finally, it will be appreciated that a variety of means may be profitably employed to perform the functions, enumerated herein, of connectors 206 and 306. Accordingly, connectors 206 and 306 are but examples of means for physically and electrically connecting wireless PC card 200 and combination PC card 300, respectively, to host computer 400. It should be understood that the embodiment of connectors 206 and 306 is presented herein solely by way of example and should not be construed as limiting the scope of the present invention in any way.

To briefly summarize, embodiments of the present invention include a variety of useful and desirable features and advantages. For example, one such feature relates to the form factor of PC card communication system 100. Specifically, embodiments of the present invention are configured so that a Type II wireless PC card may be contemporaneously employed with a combination PC card, having one or more full height connectors, in a single Type III PC card slot having two adjacent electrical connectors. As another example, embodiments of wireless PC card 200 and combination PC card 300 of PC card communication system 100 are configured and arranged, with respect to each other, in a manner that is sensitive to the specific geometric and operational requirements of the respective PC cards. As a final example of useful features of embodiments of the present invention, wireless PC card 200 and combination PC card 300 are each configured and arranged, with respect to each other, to permit removal of combination PC card 300 from PC card slot 402, without also necessitating the removal of wireless PC 200 card residing in the same PC card slot.

It will be appreciated that the foregoing are simply exemplary features and advantages and, accordingly, should not be construed or interpreted to constitute, in any way, an exhaustive enumeration of features and advantages of embodiments of the present invention.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed and desired to be secured by United States Letters Patent is:

1. A modular card system for electrically and physically interfacing with a slot of a host electrical device, the modular card system comprising:
(a) a first modular card conforming to a first form factor and comprising:
(i) an outer housing;
(ii) a recess at least partially formed within the outer housing;
(iii) first electronic circuitry substantially disposed within said outer housing; and
(iv) means for physically and electrically connecting first modular card to the host electrical device via the slot; and
(b) a second modular card conforming to a second form factor, the second modular card comprising:
(i) an outer housing;
(ii) second electronic circuitry substantially disposed within said housing of said second modular card; and
(iii) means for physically and electrically connecting said second modular card to the host electrical device via the slot.

2. The modular card system as recited in claim 1, wherein said first modular card comprises a wireless PC card.

3. The modular card system as recited in claim 1, wherein the first modular card further comprises at least one antenna disposed within the housing at a point substantially adjacent to the recess.

4. The modular card system as recited in claim 1, wherein said first form factor comprises a PCMCIA Type II form factor.

5. The modular card system as recited in claim 1, wherein at least a portion of said second form factor has a height substantially equal to or less than the height specified by the PCMCIA Type III form factor.

6. The modular card system as recited in claim 1, wherein said second electronic circuitry comprises analog modem circuitry, and the portion of the outer housing of the second modular card includes at least one modular connector receptacle electrically connected to the analog modem circuitry.

7. The modular card system as recited in claim 1, wherein said second electronic circuitry comprises a network interface circuitry, and the portion of the outer housing of the second modular card includes at least one modular connector receptacle interface circuitry.

8. The modular card system as recited in claim 1, wherein the portion of the outer housing that is to be received with the recess is comprised of a connector body is substantially centered in a front edge of said housing of said second PC card.

9. The modular card communication system as recited in claim 8, wherein the connector body comprises at least one RJ-type connector.

10. The modular card system as recited in claim 8, wherein the connector body comprises an RJ-11 connector and an RJ-45 connector.

11. The modular card system as recited in claim 1, wherein the first and second modular cards, when received within the slot, together form a predefined form factor that corresponds substantially to the PCMCIA Type III standard.

12. A computer system configured for both hardwire and wireless communication, the computer system comprising:
(a) a host computer including a PC card slot conforming to a first form factor; and
(b) a PC card communication system compatible with said PC card slot and comprising:
(ii) a first PC card conforming to a second form factor and comprising:
(1) a housing defining a recess;
(2) antennae disposed substantially within said housing;
(3) first electronic circuitry substantially disposed within said housing of said first PC card and being in communication with said antennae; and
(4) means for physically and electrically connecting said first PC card to said host computer; and
(i) a second PC card conforming to a third form factor, said third form factor being different from said second form factor, and said second PC card comprising:
(1) a housing;
(2) at least one connector, said at least one connector including a connector body configured and arranged so that when said connector body is at least partially received in said recess defined by said first PC card, said first and second PC cards collectively conform to a third form factor;
(3) second electronic circuitry substantially disposed within said housing of said second PC card and being in communication with said at least one connector; and
(4) means for physically and electrically connecting said second PC card to said host computer.

13. The computer system as recited in claim 12, wherein said connector body and said recess are arranged and configured so that when said first PC card and said second PC card simultaneously reside in said PC card slot, said second PC card can be removed from said PC card slot without requiring removal of said first PC card.

14. The computer system as recited in claim 12, wherein said first PC card comprises a wireless PC card.

15. The computer system as recited in claim 12, wherein said antennae comprise first and second antennae arranged so that said first antenna is disposed on a first side of said recess and said second antenna is disposed on a second side of said recess opposite said first side.

16. The computer system as recited in claim 12, wherein said first form factor comprises a PCMCIA Type III form factor.

17. The computer system as recited in claim 12, wherein said second form factor comprises a PCMCIA Type II form factor.

18. The computer system as recited in claim 12, wherein said third form factor comprises a PCMCIA Type III form factor.

19. The computer system as recited in claim 12, wherein said PC card communication system is configured for substantially simultaneous communication with at least one wireless remote device and at least one hardwired remote device.

20. The computer system as recited in claim 12, wherein said at least one connector comprises at least one RJ-type connector.

21. The computer system as recited in claim 12, wherein said second electronic circuitry comprises a network interface card in communication with said at least one connector.

22. The computer system as recited in claim 12, wherein said second electronic circuitry comprises an analog modem in communication with said at least one connector.

23. The computer system as recited in claim 12, wherein said connector body is substantially centered in a front edge of said housing of said second PC card.

24. The computer system as recited in claim 12, wherein said first form factor is the same as said third form factor.

25. A PC card communication system for facilitating communication between a host computer and a remote device, the PC card system comprising:
(a) a Type III PC card comprising:
(i) a housing;
(ii) at least one RJ-type connector, said at least one RJ-type connector including a connector body substantially centered in a front edge of said housing of said Type III PC card;
(iii) first electronic circuitry substantially disposed within said housing of said Type III PC card and being in communication with said at least one RJ-type connector; and
(iv) means for physically and electrically connecting said Type III PC card to the host computer; and
(b) a Type II PC card comprising:
(i) a housing including first and second extending portions which cooperate to define a recess configured to receive at least a portion of said connector body of said Type III PC card;
(ii) first and second antennae disposed in said first and second extending portions, respectively;
(iii) second electronic circuitry substantially disposed within said housing of said Type II PC card and being in communication with said first and second antennae; and
(iv) means for physically and electrically connecting said Type II PC card to the host computer.

26. The PC card communication system of claim 25, wherein said at least one RJ-type connector comprises an RJ-11 connector and an RJ-45 connector.

27. The PC card communication system of claim 25, wherein said first electronic circuitry comprises an analog modem and a network interface card.

28. The PC card communication system of claim 25, wherein when said at least a portion of said connector body is received in said recess, said PC card communication system conforms with a PCMCIA Type III form factor.
